(19) United States
(12) Patent Application Publication
(10) Pub. No.: US 2005/0182627 A1
(43) Pub. Date: Aug. 18, 2005

(54) Audio signal processing apparatus and audio signal processing method

(76) Inventors: Izuru Tanaka, Kanagawa (JP); Kenichi Iida, Saitama (JP); Satoshi Mihara, Kanagawa (JP); Eiichi Yamada, Tokyo (JP)

Correspondence Address: William S. Frommer, Esq.;FROMMER LAWRENCE & HAUG LLP, 745 Fifth Avenue, New York, NY, 10151, US

(21) Appl. No.: 11/036,533

(22) Filed: Jan. 13, 2005

(30) Foreign Application Priority Data
Jan. 14, 2004 (JP) 2004-006456

(51) Int. Cl. H03G 7/00

(52) U.S. Cl. 704/248; 704/214

(57) ABSTRACT

An audio-feature analyzer automatically detects points of change in audio signals to be processed. A central processing unit (CPU) obtains point-of-change information indicating positions of the points of change in the audio signals, and the point-of-change information is recorded on a data storage device. The CPU identifies point-of-change information in accordance with an instruction input by a user via a key operation unit, and audio data corresponding to the point-of-change information identified is located so that processing such as playback of audio data to be processed can be started therefrom.

### BACKGROUND OF THE INVENTION

1. Field of the Invention

The present invention relates to various apparatuses for processing audio signals, for example, IC (integrated circuit) recorders, MD (mini disc) recorders, or personal computers, and to methods used in the apparatuses.

2. Description of the Related Art

Minutes preparing apparatuses for carrying out speech recognition on recorded audio data to convert the audio data into text data, thereby automatically creating minutes, have been proposed, as disclosed, for example, in Japanese Unexamined Patent Application Publication No. 2-206825. Such techniques allow automatically preparing minutes of a meeting quickly. However, in some cases, it is desired to prepare minutes of only important parts instead of preparing minutes based on all the recorded audio data. In such cases, it is needed to find parts of interest from the recorded audio data.

For example, when the proceedings of a long meeting has been recorded using an IC recorder, an MD recorder, or the like, in order to find parts of interest from the recorded audio data, it is needed to play back the audio data and to listen to the sound played back. Although it is possible to find parts of interest using fast forwarding or fast reversing, this often takes labor and time. Thus, recording apparatuses that are capable of embedding (assigning) marks that facilitate searching in recorded data have been proposed. For example, in an MD recorder, such a function is implemented as a function of attaching track marks.

However, the function of attaching marks that facilitate searching to audio data is used by manual operations by a user as described above, so that marks cannot be assigned without user's operations. Thus, even if a user tries to perform operations for attaching marks to parts the user considers to be important during recording, the user could forget to perform the operations for attaching marks, for example, when the user is concentrated on the proceedings of the meeting.

Furthermore, even if the user assigns a mark to speech of interest, since the operation for embedding the mark is performed upon listening to the speech of interest, the mark is recorded after the speech of interest. Thus, in order to listen to the speech of interest, the user has to perform operations for moving playback position to the mark and then moving backward a little. It is cumbersome and stressful for the user if the user goes forward or backward past a part of interest and has to repeat the operation.

Furthermore, the content of a part with a mark is not known until it is listened to. If the part is found to be not a part of interest by listening to it, an operation for moving to a next mark must be repeated until the part of interest is found, which is also laborious. As described above, although the function of assigning marks that facilitate searching to audio data is convenient, when, for example, the user is not accustomed to the operations, the function of assigning marks to parts of interest of audio data does not work sufficiently.

### SUMMARY OF THE INVENTION

Accordingly, it is an object of the present invention to provide an apparatus and method that readily allows a user to quickly find and use parts of interest in audio signals to be processed.

In order to achieve the object, according to an aspect of the present invention, an audio-signal processing apparatus is provided. The audio signal processing apparatus includes a first detecting unit for detecting speaker change in audio signals to be processed, based on the audio signals, on a basis of individual processing units having a predetermined size; an obtaining unit for obtaining point-of-change information indicating a position of the audio signals where the first detecting unit has detected a speaker change; and a holding unit for holding the point-of-change information obtained by the obtaining unit.

In the audio-signal processing apparatus, the detecting unit automatically detects points of change in audio signals to be processed, the obtaining unit obtains point-of-change information indicating positions of the points of change in the audio signals, and the holding unit holds the point-of-change information. Holding the point-of-change information indicating the positions of the points of change is equivalent to assigning marks to the points of change in the audio signals to be processed.

The point-of-change information detected and held as described above allows locating audio signals corresponding to the point-of-change information so that processing such as playback of the audio signals to be processed can be started from the position. Thus, a user is allowed to quickly find parts of interest from the audio signals with reference to marks automatically assigned to the points of change in the audio signals, without performing cumbersome operations.

Preferably, the first detecting unit is capable of extracting features of the audio signals on the basis of the individual processing units, and detecting a point of change from a non-speech segment to a speech segment and a point of speaker change in a speech segment based on the features extracted.

Accordingly, the detecting unit detects features of audio signals to be processed on a basis of individual processing units having a predetermined size, and executes processing such as comparing the features with features detected earlier. Thus, the detecting unit is capable of detecting a point of change from a silent segment or a noise segment to a speech segment and a point of speaker change in a speech segment.

Thus, marks can be assigned at least to points of speaker change, so that it is possible to quickly find parts of interest from audio data with reference to the points of speaker change.

The audio-signal processing apparatus may further include a storage unit for storing one or more pieces of feature information representing features of speeches of one or more speakers, and one or more pieces of identification information of the one or more speakers, the pieces of feature information and the pieces of identification information being respectively associated with each other; and an identifying unit for identifying a speaker by comparing the features extracted by the first detecting unit with the pieces of feature information stored in the storage unit. In that case, the holding unit holds the point-of-change information and a piece of identification information of the speaker identified by the identifying unit, the point-of-change information and the piece of identification information being associated with each other.

In the audio-signal processing apparatus, pieces of feature information representing features of speeches of speakers and pieces of identification information of the speakers are stored in association with each other in the storage unit. The identifying unit identifies a speaker at a point of change by comparing the features extracted by the first detecting unit with the pieces of feature information stored in the storage unit. The holding unit holds the point-of-change information and a piece of identification information of the speaker identified.

Accordingly, it is possible to play back or extract parts corresponding to speech of a specific speaker, and to quickly find parts of interest from audio data based on the identities of speakers at respective points of change.

The audio-signal processing apparatus may further include a second detecting unit for detecting a speaker position by analyzing audio signals of a plurality of audio channels respectively associated with a plurality of microphones. In that case, the obtaining unit identifies a point of change in consideration of change in speaker position detected by the second detecting unit, and obtains point-of-change information corresponding to the point of change identified.

In the audio-signal processing apparatus, the second detecting unit detects a speaker position by analyzing audio signals of respective audio channels, detecting a point of change in audio signals to be processed. The obtaining unit identifies a point of change that is actually used, based on both a point of change detected by the first detecting unit and a point of change detected by the second detecting unit, and obtains point-of-change information indicating a position of the point of change identified.

Accordingly, a point of change in audio signals can be detected more accurately and reliably in consideration of a point of change detected by the second detecting unit, allowing searching of parts of interest from audio data.

The audio-signal processing apparatus may further include a speaker-information storage unit for storing speaker positions determined based on audio signals of a plurality of audio channels respectively associated with a plurality of microphones, and pieces of identification information of speakers at the respective speaker positions, the speaker positions being respectively associated with the pieces of identification information; and a speaker-information obtaining unit for obtaining, from the speaker-information storage unit, a piece of identification information of a speaker associated with a speaker position determined by analyzing the audio signals of the plurality of audio channels. In that case, the identifying unit identifies the speaker in consideration of the identification information obtained by the speaker-information obtaining unit.

In the audio-signal processing apparatus, the speaker-information storage unit stores speaker positions determined based on audio signals of a plurality of audio channels respectively associated with a plurality of microphones, and pieces of identification information of speakers at the respective speaker positions. That is, positions of speakers are determined based on positions where the respective microphones are provided. For example, a speaker who is nearest to the position of a first microphone is A, and a speaker who is nearest to the position of a second microphone is B. Thus, it is possible to determine which microphone a current speaker is associated with, for example, based on which microphone is associated with an audio channel of audio data having a highest level.

The speaker-information obtaining unit analyses audio data of the respective audio channels, identifying a speaker position based on which audio channel is associated with a microphone that has been mainly used to collect speech. The identifying unit identifies a speaker at a point of change in consideration of the identification obtained in the manner described above. Accordingly, accurate information can be used to search for parts of interest from audio data to be processed, so that the accuracy of speaker identification is improved.

The audio-signal processing apparatus may further include a display-information processing unit. In that case, the storage unit stores pieces of information respectively relating to the speakers corresponding to the respective pieces of identification information, the pieces of information being respectively associated with the respective pieces of identification information, and the display-information processing unit displays a position of a point of change in the audio signals and a piece of information relating to the speaker identified by the identifying unit.

In the audio-signal processing apparatus, the storage unit stores pieces of information respectively relating to the speakers corresponding to the respective pieces of identification information, for example, various image data or graphic data such as face-picture data, icon data, mark-image data, or animation-image data, in association with the respective pieces of identification information. The display-information processing unit displays a position of a point of change and a piece of information relating to the speaker identified by the identifying unit.

Accordingly, a user can visually find parts corresponding to speeches of respective speakers in audio data to be processed. Thus, the user can quickly find parts of interest in the audio data to be processed.

In the audio-signal processing apparatus the first detecting unit may detect speaker change based on a speaker position determined by analyzing audio signals of respective audio channels, the audio signals being collected by different microphones.

In the audio-signal processing apparatus, a speaker position is identified by analyzing audio signals of respective audio channels, and a point of change in speaker position is detected as a point of change.

Accordingly, by analyzing audio signals of respective audio channels, points of change in audio signals to be processed can be detected easily and accurately, and marks can be assigned to points of speaker change. Furthermore, it is possible to quickly find parts of interest from audio data with reference to the points of speaker change.

Preferably, in the audio-signal processing apparatus, the holding unit holds the point-of-change information and information indicating the speaker position detected by the first detecting unit, the point-of-change information and the information indicating the speaker position being associated with each other.

In the audio-signal processing apparatus, information held in the holding unit can be provided to a user. Accordingly, the user is allowed to find a speaker position of a speaker speaking at each point of change, and to find parts of interest from audio data to be processed.

The audio-signal processing apparatus may further include a speaker-information storage unit for storing speaker positions determined based on audio signals of a plurality of audio channels respectively associated with a plurality of microphones, and pieces of identification information of speakers at the respective speaker positions, the speaker positions being respectively associated with the pieces of identification information; and a speaker-information obtaining unit for obtaining, from the speaker-information storage unit, a piece of identification information of a speaker associated with a speaker position determined by analyzing the audio signals of the plurality of audio channels. In that case, the holding unit holds the point-of-change information and the piece of identification information obtained by the speaker-information obtaining unit, the point-of-change information and the piece of identification information being associated with each other.

In the audio-signal processing apparatus, the speaker-information storage unit stores speaker positions determined based positions of microphones, and pieces of identification information of speakers at respective speaker positions, the speaker positions and the pieces of identification information being respectively associated with each other. The speaker-information obtaining unit identifies a speaker position by analyzing audio signals of respective audio channels. The holding unit holds the point-of-change information and a piece of identification information obtained by the speaker-information obtaining unit, the point-of-change information and the piece of identification information being associated with each other.

Accordingly, it is possible to identify a speaker at each point of change, and to provide the information to a user. Thus, it is possible to easily and accurately find parts of interest from audio data to be processed.

The audio-signal processing apparatus may include a display-information processing unit. In that case, the speaker-information storage unit stores pieces of information respectively relating to the speakers corresponding to the respective pieces of identification information, the pieces of information being respectively associated with the respective pieces of identification information, and the display-information processing unit displays a position of a point of change in the audio signals and a piece of information relating to the speaker associated with the speaker position determined.

In the audio-signal processing apparatus, the speaker-information storage unit stores pieces of information respectively relating to the speakers corresponding to the respective pieces of identification information, for example, various image data or graphic data such as face-picture data, icon data, mark-image data, or animation-image data, in association with the respective pieces of identification information. The display-information processing unit displays a position of a point of change and a piece of information relating to the speaker identified by the identifying unit.

Accordingly, a user can visually find parts corresponding to speeches of respective speakers in audio data to be processed. Thus, the user can quickly find parts of interest in the audio data to be processed.

According to another aspect of the present invention, an audio-signal processing method is provided. The audio-signal processing method includes a first detecting step of detecting speaker change in audio signals to be processed, based on the audio signals, on a basis of individual processing units having a predetermined size; an obtaining step of obtaining point-of-change information indicating a position of the audio signals where a speaker change has been detected in the first detecting step; and a storing step of storing the point-of-change information obtained in the obtaining step on a recording medium.

According to the present invention, even when a long meeting is recorded, a speaker-change mark is automatically assigned each time a speaker change occurs. This improves ease of searching for speech in preparing minutes, allowing parts corresponding to speech of a speaker of interest to be repeatedly played back easily and quickly.

Furthermore, it is possible to identify a speaker at a point of change in audio data and to manage information indicating the speaker in association with the point of change. Thus, it is possible to easily and quickly find parts corresponding to speech of a specific speaker without playing back the audio data.

Furthermore, dependency on the memory of a person who creates minutes is alleviated. This serves to improve the efficiency of the work of preparing minutes, which has been laborious and time-consuming. Furthermore, it is possible to use recorded data as minutes in the form of audio data without creating minutes. This improves ease of searching.

### BRIEF DESCRIPTION OF THE DRAWINGS

FIG. 1 is a block diagram of a recording/playback apparatus according to an embodiment of the present invention;

FIG. 2 is a diagram for explaining a scheme of a process for assigning marks to points of change in collected audio signals that are recorded by the recording/playback apparatus;

FIG. 3 is a diagram showing how information displayed on an LCD changes in accordance with operations when setting playback position to marks during playback of recorded audio signals;

FIG. 4 is a flowchart of a recording process executed by the recording/playback apparatus shown in FIG. 1;

FIG. 5 is a flowchart of a playback process executed by the recording/playback apparatus shown in FIG. 1;

FIG. 6 is a diagram showing an example of audio-feature database created in a storage area of an external storage device of the recording/playback apparatus shown in FIG. 1;

FIG. 7 is a diagram for explaining a scheme of a process for assigning marks to collected audio signal in the recording/playback apparatus shown in FIG. 1;

FIG. 8 is a diagram showing how information displayed on the LCD changes in accordance with operations when setting playback position to marks during playback of recorded audio signals;

FIG. 9 is a flowchart of a process for assigning marks to points of change in recorded audio signals after the recording process;

FIG. 10 is a diagram showing an example of point-of-change information displayed on a screen of a display in accordance with data transferred to a personal computer from the recording/playback apparatus shown in FIG. 1;

FIG. 11 is a diagram showing an example of point-of-change information displayed on a screen of a display in accordance with data transferred to a personal computer from the recording/playback apparatus shown in FIG. 1;

FIG. 12 is a block diagram of a recording/playback apparatus according to another embodiment of the present invention;

FIG. 13 is a diagram showing an example of microphones and an audio-signal processor;

FIG. 14 is a diagram showing another example of microphones and an audio-signal processor;

FIGS. 15A and 15B are diagrams for explaining a process for assigning marks to points of change in recorded audio signals after the recording process;

FIG. 16 is a diagram showing an example of speaker-position database;

FIGS. 17A and 17B are diagrams for explaining other example schemes for identifying a speaker by identifying a speaker position based on signals output from microphones; and

FIG. 18 is a block diagram of a recording/playback apparatus according to another embodiment of the present invention.

### DESCRIPTION OF THE PREFERRED EMBODIMENTS

Now, apparatuses, methods, and programs according to embodiments of the present invention will be described with reference to the drawings. The embodiments will be described in the context of examples where the present invention is applied to an IC recorder, which is an apparatus for recording and playing back audio signals.

### First Embodiment

### Overview of Construction and Operation of IC Recorder

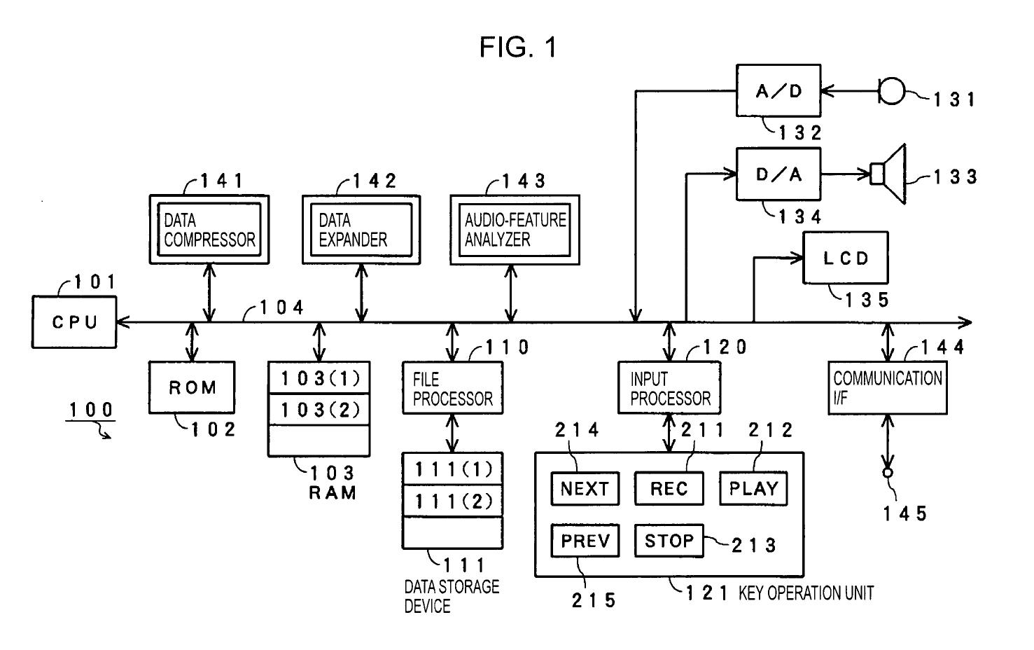

FIG. 1 is a block diagram of an IC recorder that is a recording/playback apparatus according to a first embodiment of the present invention. Referring to FIG. 1, the IC recorder according to the first embodiment includes a controller 100 implemented by a microcomputer. The controller 100 includes a central processing unit (CPU) 101, a read-only memory (ROM) 102 storing programs and various data, and a random access memory (RAM) 103 that is used mainly as a work area, these components being connected to each other via a CPU bus 104. As will be described later, the RAM 103 includes a compressed-data area 103(1) and a PCM (pulse code modulation)-data area 103(2).

The controller 100 is connected to a data storage device 111 via a file processor 110, and is connected to a key operation unit 121 via an input processor 120. Furthermore, the controller 100 is connected to a microphone 131 via an analog/digital converter (hereinafter abbreviated as an A/D converter) 132, and is connected to a speaker 133 via a digital/analog converter (hereinafter abbreviated as a D/A converter) 134. Furthermore, the controller 100 is connected to a liquid crystal display (LCD) 135. In this embodiment, the LCD 135 includes functions of an LCD controller.

Furthermore, the controller 100 is connected to a data compressor 141, a data expander 142, an audio-feature analyzer 143, and a communication interface (hereinafter abbreviated as a communication I/F) 144. The functions of the data compressor 141, the data expander 142, and the audio-feature analyzer 143, indicated by double lines in FIG. 1, can also be implemented in software (i.e., programs) executed by the CPU 101 of the controller 100.

In the first embodiment, the communication I/F 144 is a digital interface, such as a USB (Universal Serial Bus) interface or IEEE (Institute of Electrical and Electronics Engineers)-1394 interface. The communication I/F 144 allows exchanging data with various electronic devices connected to a connecting terminal 145, such as a personal computer or a digital camera.

In the IC recorder according to the first embodiment, when a REC key (recording key) 211 of the key operation unit 121 is pressed, the CPU 101 controls relevant components to execute a recording process. In the recording process, sound is collected by the microphone 131, the collected sound is A/D-converted by the A/D converter 132, the resulting digital data is compressed by the data compressor 141, and the resulting audio signals are recorded in a predetermined storage area of the data storage device 111 via the file processor 110.

The data storage device 111 in the first embodiment is a flash memory or a memory card including a flash memory. As will be described later, the data storage device 111 includes a database area 111(1) and an audio file 111(2).

In the recording process, the IC recorder according to the first embodiment, by the functions of the audio-feature analyzer 143, analyzes features of collected audio signals that are recorded, individually for each processing unit of a predetermined size. When changes in features are detected, the IC recorder assigns marks to the points of change. These marks allow quick searching for intended audio-signal segments from recorded audio signals.

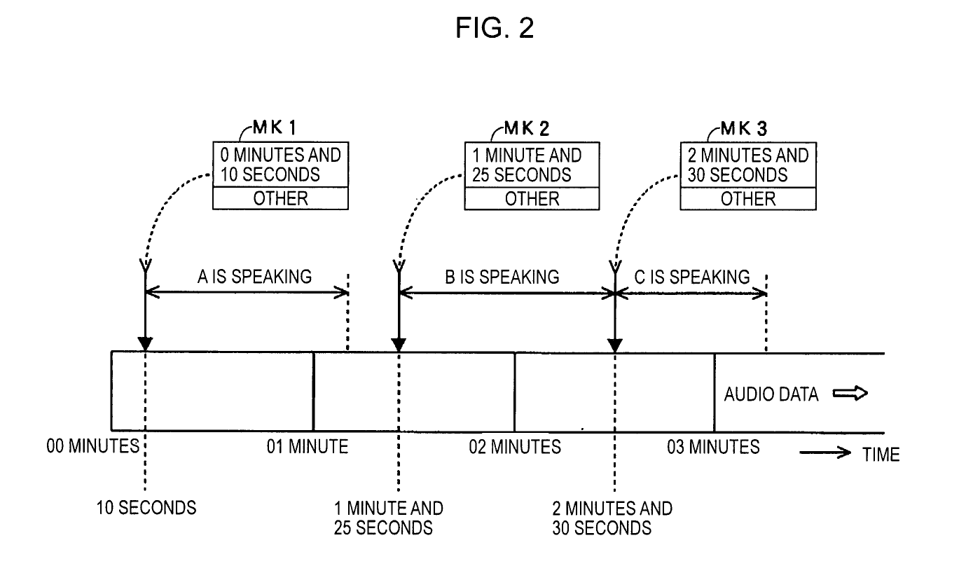

FIG. 2 is a diagram for explaining the scheme of a process for assigning marks at points of change in collected audio signals that are recorded. As described above, in the IC recorder according to the first embodiment, features of audio signals collected by the microphone 131 are analyzed individually for each processing unit of a predetermined size.

By comparing results of feature analysis of a current processing unit with results of feature analysis of an immediately previous processing unit, a point of change from a silent segment or a noise segment to a speech segment, or a point where the speaker changes in a speech segment, is detected, identifying a temporal position of the change in the audio signals. Then, the position identified is stored in the data storage device 111 as point-of-change information (mark information). In this manner, marking collected audio signals that are recorded is achieved by storing point-of-change information indicating positions of points of change in the audio signals.

As an example, a case where the proceedings of a meeting are recorded will be considered. Let it be supposed that A starts speaking 10 seconds after recording is started, as shown in FIG. 2. In this case, before A starts speaking, what is collected is silence, or meaningless sound that differs from clear speech, i.e., noise such as babble, the sound of pulling up a chair, or the sound of an item hitting a table. When A starts speaking and A's speech is collected, results of feature analysis of collected audio signals become clearly different from those before A starts speaking.

A point of change in the collected audio signals that are recorded is detected by the audio-feature analyzer 143, a position of the point of change in the audio signals is identified (obtained), and point-of-change information indicating the identified position in the audio signals is stored in the data storage device 111 as a mark MK1 in FIG. 2. FIG. 2 shows an example where time elapsed since recording is started is stored as point-of-change information.

Let it be supposed further that B starts speaking a little after A stops speaking. The period immediately before B starts speaking is a segment of silence or noise. Also in this case, when B starts speaking and B's speech is collected, results of feature analysis of the collected audio signals become clearly different from those before B starts speaking. Thus, as indicated by a mark MK2 in FIG. 2, point-of-change information (the mark MK2) is stored in the data storage device 111 so that a mark is assigned to the start point of the B's speech.

Furthermore, it could occur that C interrupts while B is speaking. In that case, since the voice of B differs from the voice of C, results of analyzing collected audio signals differ between B and C. Thus, as indicated by a mark MK3 in FIG. 2, point-of-change information (the mark MK3) is stored in the data storage device 111 so that a mark is assigned to the start point of the C's speech.

As described above, in the recording process by the IC recorder according to the first embodiment, features of collected audio signals are analyzed and points of change in features of the audio signals are stored. Thus, marks can be assigned to the points of change in features of the audio signals.

Referring to FIG. 2, “Others” sections of the marks MK1, MK2, and MK3 allow related information to be stored together in association with the marks. For example, if speech is converted into text data by speech recognition, the text data is stored together with an associated mark.

In the IC recorder according to the first embodiment, when a PLAY key (playback key) 212 of the key operation unit 121 is pressed, the CPU 101 controls relevant components to execute a playback process. More specifically, compressed digital audio signals recorded in a predetermined storage area of the data storage device 111 are read via the file processor 110, and the digital audio signals are expanded by the data expander 142, whereby original digital audio signals before compression are restored. The restored digital audio signals are converted into analog audio signals by the D/A converter 134, and the analog signals are supplied to the speaker 133. Thus, sound corresponding to the recorded audio signals to be played back is produced.

In the playback process by the IC recorder according to the first embodiment, when a NEXT key (a key for locating a next mark) 214 or a PREV key (a key for locating a previous mark) 215 of the key operation unit 121 is operated, playback position is quickly set to the position of the relevant mark so that playback is started therefrom.

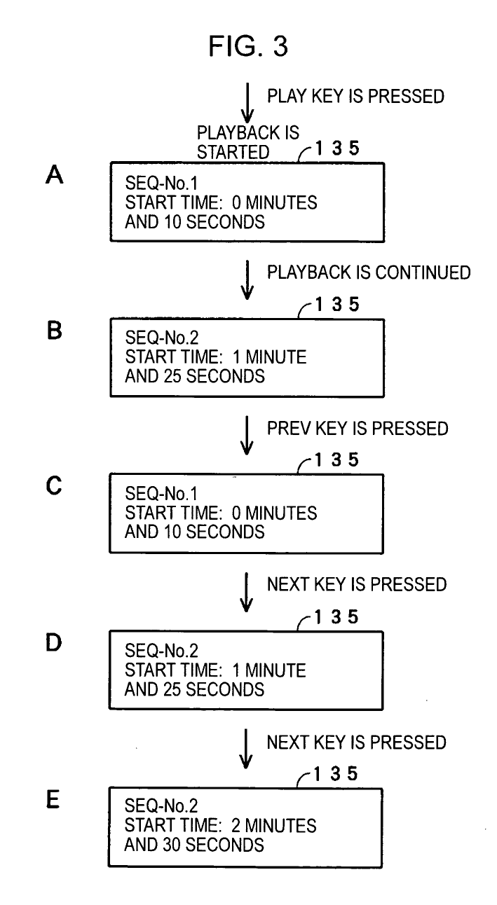

FIG. 3 is a diagram showing change in information displayed on the LCD 135 in accordance with operations, which serves to explain an operation for locating a position indicated by a mark on recorded audio signals when the recorded audio signals are played back. Referring to FIG. 3, when the PLAY key 211 is pressed, as described earlier, the CPU 101 controls relevant components to start playback from the beginning of recorded audio signals specified.

In the part corresponding to A's speech, based on the mark MK1 assigned in the recording process as described with reference to FIG. 2, the start time of A's speech is displayed, together with “SEQ-No.1” indicating that the mark is the first mark assigned after the start of recording, as shown in part A of FIG. 3.

When playback is continued and playback of the part corresponding to B's speech is started, the start time of B's speech is displayed, together with “SEQ-No.2” indicating that the mark is the second mark assigned after the start of recording, as shown in part B of FIG. 3. Then, when the PREV key 215 is pressed, the CPU 101 sets the playback position to start point of A's speech, that is, at 10 seconds (0 minutes and 10 seconds) from the beginning, indicated by the mark MK1, so that playback is resumed therefrom, as shown in part C of FIG. 3.

Then, when the NEXT key 214 is pressed, the CPU 101 sets the playback position to the start point of B's speech, that is, at 1 minute and 25 seconds from the beginning, indicated by the mark MK2, so that playback is resumed therefrom, as shown in part D of FIG. 3. When the NEXT key 214 is pressed again, the CPU 101 sets the playback position to the start point of C's speech, that is, at 2 minutes and 30 seconds from the beginning, indicated by the mark MK3, so that playback is resumed therefrom, as shown in part E of FIG. 3.

As described above, in the IC recorder according to the first embodiment, in the recording process, features of collected audio signals are analyzed automatically and marks are assigned to points of change in features. Furthermore, in the playback process, by operating the NEXT key 214 or the PREV key 215, the playback position can be quickly set to a point of recorded audio signals, indicated by an assigned mark, so that playback is started therefrom.

This allows a user to quickly set the playback position to speech by speaker of interest and to play back and listen to part of the recorded audio signals. Thus, the user can quickly prepare minutes regarding speeches of interest.

Although information indicating time elapsed from the start of recording is used as point-of-change information in the first embodiment for simplicity of description, without limitation thereto, for example, an address of audio signals recorded on a recording medium of the data storage device 111 may be used as point-of-change information.

### Details of Operation of IC Recorder

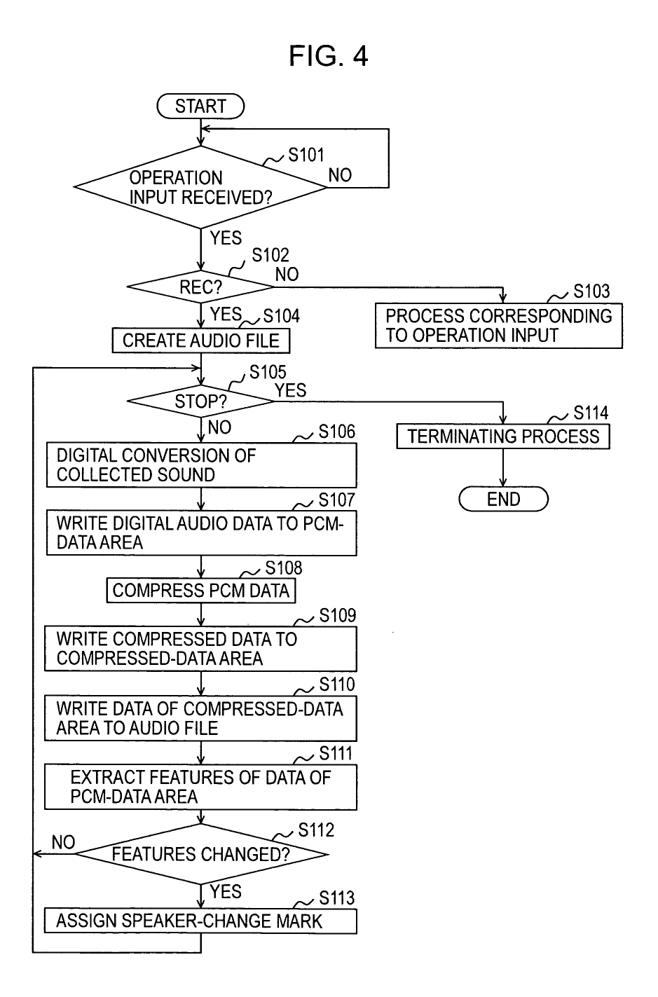

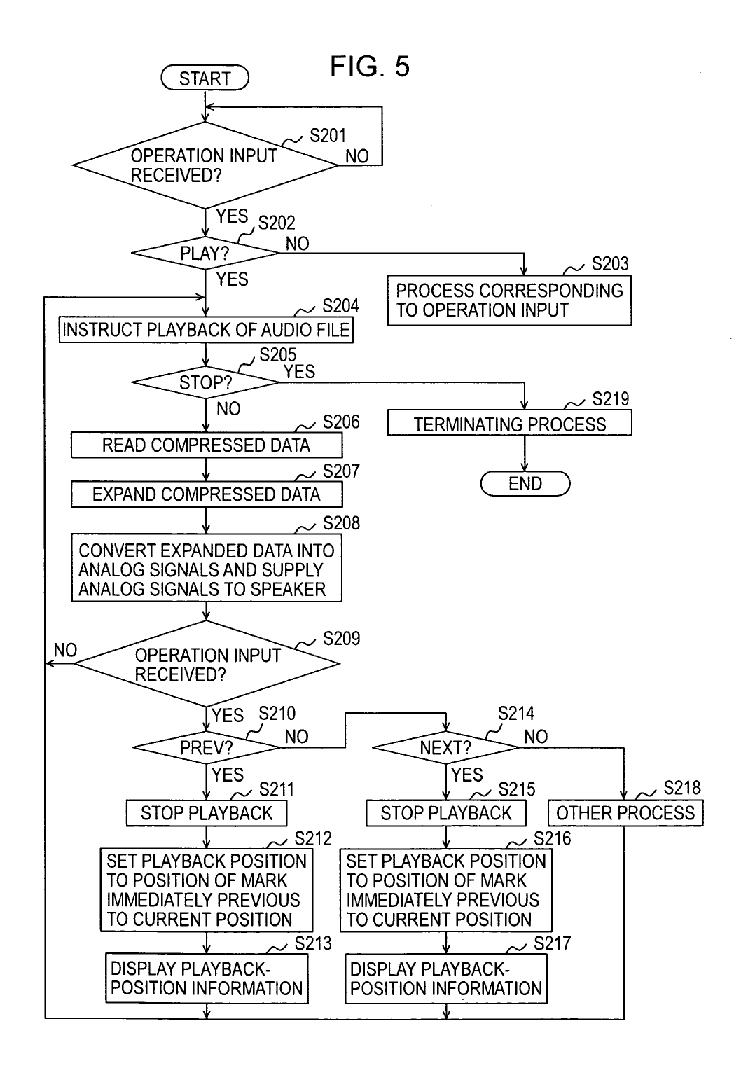

Next, the recording process and the playback process executed by the IC recorder according to the first embodiment will be described in detail with reference to flowcharts shown in FIG. 4 and 5.

### Recording Process

First, the recording process will be described. FIG. 4 is a flowchart showing the recording process executed by the IC recorder according to the first embodiment. The process shown in FIG. 4 is executed by the CPU 101 controlling relevant components.

The IC recorder according to the first embodiment, when it is powered on but is not in operation, waits for input of an operation by a user (step S101). When the user presses an operation key of the operation unit 121, the input processor 120 detects the operation and notifies the CPU 101 of the operation. The CPU 101 determines whether the operation accepted is pressing of the REC key 211 (step S102).

If it is determined in step S102 that the operation accepted is not pressing of the REC key 211, the CPU 101 executes a process corresponding to the key operated by the user, e.g., a playback process corresponding to the PLAY key 212, a process for locating a next mark, corresponding to the NEXT key 124, or a process for locating a previous mark, corresponding to the PREV key 215 (step S103). Obviously, fast forwarding and fast reversing are also allowed.

If it is determined in step S102 that the REC key has been pressed, the CPU 101 instructs the file processor 110 to execute a file recording process. In response to the instruction, the file processor 110 creates an audio file 111(2) in the data storage device 111 (step S104).

Then, the CPU 101 determines whether the STOP key 213 of the key operation unit 121 has been pressed (step S105). If it is determined in step S105 that the STOP key 213 has been pressed, a predetermined terminating process is carried out (step S114) as will be described later, and the process shown in FIG. 4 is exited.

If it is determined in step S105 that the STOP key 213 has not been pressed, the CPU 101 instructs the A/D converter 132 to convert analog audio signals input via the microphone 131 into digital audio signals so that collected sound is digitized (step S106).

In response to the instruction, the A/D converter 132 converts analog audio signals input via the microphone 131 into digital audio signals at a regular cycle (i.e., for each processing unit of a predetermined size), writes the digital audio signals in the PCM-data area 103(2) of the RAM 103, and notifies the CPU 101 of the writing (step S107).

In response to the notification, the CPU 101 instructs the data compressor 141 to compress the digital audio signals (PCM data) stored in the PCM-data area 103(2) of the RAM 103 (step S108). In response to the instruction, the data compressor 141 compresses the digital audio signals in the PCM-data area 103(2) of the RAM 103, and writes the compressed digital audio signals to the compressed-data area 103(1) of the RAM 103 (step S109).

Then, the CPU 101 instructs the file processor 110 to write the compressed digital audio signals in the compressed-data area 103(1) of the RAM 103 to the audio file 111(2) created in the data storage device 111. Accordingly, the file processor 110 writes the compressed digital audio signals in the compressed-data area 103(1) of the RAM 103 to the audio file 111(2) of the data storage device 111 (step S110).

The file processor 110, upon completion of writing of the compressed digital audio signals to the audio file 111(2), notifies the CPU 101 of the completion. Then, the CPU 101 instructs the audio-feature analyzer 143 to analyze features of the digital audio signals recorded earlier in the PCM-data area 103(2) of the RAM 103 so that the audio-feature analyzer 143 extracts features of the digital audio signals in the PCM-data area 103(2) of the RAM 103 (step S111).

The feature analysis (feature extraction) of digital audio signals by the audio-feature analyzer 143 may be based on various methods, e.g., voiceprint analysis, speech rate analysis, pause analysis, or stress analysis. For simplicity of description, it is assumed herein that the audio-feature analyzer 143 of the IC recorder according to the first embodiment uses voiceprint analysis to extract features of digital audio signals to be analyzed.

The audio-feature analyzer 143 compares audio features (voiceprint data) currently extracted with voiceprint data previously extracted to determine whether the features extracted from input audio signals have changed from the previous features, and notifies the CPU 101 of the result. Based on the result, the CPU 101 determines whether the features of collected sound have changed (step S112).

If it is determined in step S112 that the features have not changed, the CPU 101 repeats the process from step S105 to step S112 on audio signals in the next period (next processing unit).

If it is determined in step S112 that the features have changed, the CPU 101 determines that the speaker has changed, and instructs the file processor 110 to assign a mark to the point of change in features of audio signals to be processed (step S113). In response to the instruction, the file processor 110 writes information indicating the point of change in audio features regarding the audio file 111(2), e.g., information indicating a time from the beginning of the audio file 111(2) or information indicating an address of recording, to the database area 111(1) of the data storage device 111. At this time, the audio file 111(2) and the information indicating the point of change in audio features are stored in association with each other.

After step S113, the CPU 101 repeats the process from step S105 to step S112 on audio signals of a next period (next processing unit).

If it is determined in step S105 that the user has pressed the STOP key 213, the CPU 101 executes a predetermined terminating process including instructing the file processor 110 to stop writing data to the audio file 111(2) of the data storage device 111, instructing the data compressor 141 to stop compression, and instructing the A/D converter 132 to stop conversion into digital signals (step S114). The process shown in FIG. 4 is then exited.

The audio-feature analyzer 143 determines whether audio features have changed by holding audio feature data (voiceprint data) previously extracted and comparing the previous audio feature data with newly extracted audio feature data (voiceprint data). If it suffices to compare newly extracted feature data only with an immediately previous set of feature data, it suffices to constantly hold only an immediately previous set of feature data. If newly extracted feature data is to be compared with two or more sets of previous feature data to improve precision, determining that features have changed when the difference from each of the two or more sets of previous feature data is observed, it is necessary to hold two or more sets of previous feature data.

As described above, in the IC recorder according to the first embodiment, it is possible to analyze features of collected audio signals that are recorded, detect points of change in features of the collected audio signals, and assign marks to the positions of the points of change in the collected audio signals.

### Playback Process

Next, the playback process will be described. FIG. 5 is a flowchart showing the playback process executed by the IC recorder according to the first embodiment. The process shown in FIG. 5 is executed by the CPU 101 controlling relevant components.

In the playback process of the IC recorder according to the first embodiment, it is possible to quickly find intended audio-signal segments from recorded audio signals using marks assigned in the recording process to points of change in features of collected and recorded audio signals, as described with reference to FIG. 4.

The IC recorder according to the first embodiment, when it is powered on but is not in operation, waits for input of an operation by a user (step S201). When the user presses an operation key of the key operation unit 121, the input processor 120 detects the operation and notifies the CPU 101 of the operation. Then, the CPU 101 determines whether the operation accepted is pressing of the PLAY key 212 (step S202).

If it is determined in step S202 that the operation accepted is not pressing of the PLAY key 212, the CPU 101 executes a process corresponding to the key operated by the user, e.g., a recording process corresponding to the REC key 212, a process for locating a next mark, corresponding to the NEXT key 214, or a process for locating a previous mark, corresponding to the PREV key 215 (step S203). Obviously, fast forwarding and fast reversing are also allowed.

If it is determined in step S202 that the operation accepted is pressing of the PLAY key 212, the CPU 101 instructs the file processor 110 to read the audio file 111(2) on the data storage device 111 (step S204). Then, the CPU 101 determines whether the STOP key 213 of the key operation unit 121 has been pressed (step S205).

If it is determined in step S205 that the STOP key 213 has been operated, a terminating process is executed (step S219) as will be described later. The process shown in FIG. 5 is then exited.

If it is determined in step S205 that the STOP key 213 has not been operated, the CPU 101 instructs the file processor 110 to read an amount of compressed digital audio signals stored in the audio file 111(2) of the data storage device 111, the amount corresponding to a processing unit of a size predefined by the system, and to write the digital audio signals to the compressed-data area 103(1) of the RAM 103 (step S206).

When the writing is completed, the CPU 101 is notified of the completion. Then, the CPU 101 instructs the data expander 142 to expand the compressed digital audio signals in the compressed-data area 103(1) of the RAM 103. Then, the data expander 142 expands the compressed digital audio signals, and writes the expanded digital audio signals to the PCM-data area 103(2) of the RAM 103 (step S207).

When the writing is completed, the CPU 101 is notified of the completion. Then, the CPU 101 instructs the D/A converter 134 to convert the expanded digital audio signals stored in the PCM-data area 103(2) of the RAM 103 into analog signals and to supply the analog audio signals to the speaker 133.

Thus, sound corresponding to the digital audio signals stored in the audio file 111(2) of the data storage device 111 is output from the speaker 133. Then, the D/A converter 134 notifies the CPU 101 that the analog audio signals obtained by D/A conversion have been output. Then, the CPU 101 determines whether an operation key of the key operation unit 121 has been operated (step S209).

If it is determined in step S209 that no operation key has been operated, the process is repeated from step S205 to continue playback of digital audio signals in the audio file 111(2) of the data storage device 111.

If it is determined in step S209 that an operation key has been operated, the CPU 101 determines whether the key operated is the PREV key 215 (step S210). If it is determined in step S210 that the PREV key 215 has been operated, the CPU 101 instructs the file processor 110 to stop reading digital audio signals from the audio file 111(2), instructs the data expander 142 to stop expanding, and instructs the D/A converter 134 to stop conversion into analog signals (step S211).

Then, the CPU 101 instructs the file processor 110 to read information of a mark (point-of-change information) immediately previous to the current playback position from the database area 111(1) of the data storage device 111 so that the playback position is set to a position of audio signals indicated by the information of the mark and playback is started therefrom (step S212). At this time, as described with reference to FIG. 3, playback-position information corresponding to the information of the mark used for setting the playback position is displayed (step S213). Then, the process is repeated from step S205.

If it is determined in step S210 that the key operated is not the PREV key 215, the CPU 101 determines whether the key operated is the NEXT key 214 (step S214). If it is determined in step S214 that the NEXT key 214 has been operated, the CPU 101 instructs the file processor 110 to stop reading digital audio signals from the audio file 111(2), instructs the data expander 142 to stop expanding, and instructs the D/A converter 134 to stop conversion into analog signals (step S215).

Then, the CPU 101 instructs the file processor 110 to read information of a mark (point-of-change information) immediately after the current playback position from the database area 111(1) of the data storage device 111 so that the playback position is set to a position of audio signals indicated by the information of the mark and playback is started therefrom (step S216). At this time, as described with reference to FIG. 3, playback-position information corresponding to the information of the mark used for setting the playback position is displayed (step S217). Then, the process is repeated from step S205.

If it is determined in step S214 that the key operated is not the NEXT key 214, the CPU 101 executes a process corresponding to the key operated, e.g., fast forwarding or fast reversing. Then, the process is repeated from step S205.

As described above, in the recording process, the IC recorder assumes a speaker change when a change in audio features is detected, and automatically assigns a mark to the point of change. Thus, in the playback process, the user is allowed to get to the beginning of each speech simply by pressing the PREV key 215 or the NEXT key 214. This considerably facilitates preparation of minutes, for example, when repeatedly playing back a particular speech or when searching for an important speech. That is, it is possible to quickly find an intended segment from recorded audio signals.

Furthermore, points of change in features of collected audio signals are detected automatically, and marks are assigned to the points of change automatically. Thus, marks are assigned to points of change without any operation by the user.

### Modification of the First Embodiment

When the proceedings of a meeting are recorded and minutes are prepared based on the recording, it will be more convenient if it is possible to find who spoke at when without playing back the recorded sound. Thus, in an IC recorder according to a modification of the first embodiment, voiceprint data obtained by analyzing features of voices of participants of a meeting is stored in association with symbols for identifying the respective participants, thereby assigning marks that allow identification of speakers.

The IC recorder according to the modification is constructed similarly to the IC recorder according to the first embodiment shown in FIG. 1. However, in the IC recorder according to the modification, an audio-feature database regarding participants of a meeting is created, for example, in a storage area of the data storage device 111 or the RAM 103. In the following description, it is assumed that the audio-feature database is created in a storage area of the data storage device 111.

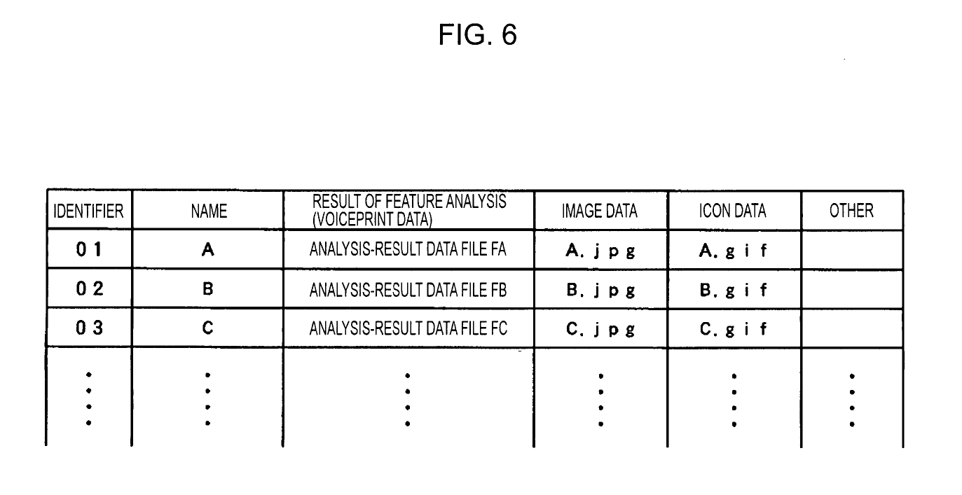

FIG. 6 is a diagram showing an example of audio-feature database created in a storage area of the data storage device 111 of the IC recorder according to the modification. As shown in FIG. 6, the audio-feature database in this example includes identifiers for identifying participants of a meeting (e.g., sequence numbers based on the order of registration), names of the participants of the meeting, voiceprint data obtained by analyzing features of voices of the participants of the meeting, image data such as pictures of the faces of the participants of the meeting, icon data assigned to the respective participants of the meeting, and other data such as text data.

Each of the voiceprint data, image data, icon data, and other data is stored in the data storage device ill in the form of a file, with the identifiers of the individual participants of the meeting as key information (associating information). The voiceprint data obtained by feature analysis is obtained in advance of the meeting by collecting voices of the participants of the meeting and analyzing features of the voices.

That is, the IC recorder according to the modification has an audio-feature-database creating mode. When the audio-feature-database creating mode is selected, voices of the participants of the meeting are collected, and features of the collected voices are analyzed to obtain voiceprint data. The voiceprint data is stored in a storage area of the data storage device 111 in association with identifiers such as sequence numbers.

Information other than the identifiers and voiceprint data, such as names, image data, and icon data, is supplied to the IC recorder according to the modification via a personal computer or the like connected to the connecting terminal 145, and is stored in association with the identifiers and voiceprint data, as shown in FIG. 6. Obviously, for example, names can be entered by operating operation keys provided on the key operation unit 121 of the IC recorder, and image data can be captured from a digital camera connected to the connecting terminal 145.

Also in the IC recorder according to the modification, as described with reference to FIGS. 1, 2, and 4, features of collected sound are analyzed to detect points of change in voiceprint data, and marks are automatically assigned to positions of audio signals corresponding to the points of change. When a point of change is detected, matching between voiceprint data of the latest collected sound and voiceprint data in the audio-feature database is checked, and the identifier of a participant with matching voiceprint data is included in a mark that is assigned.

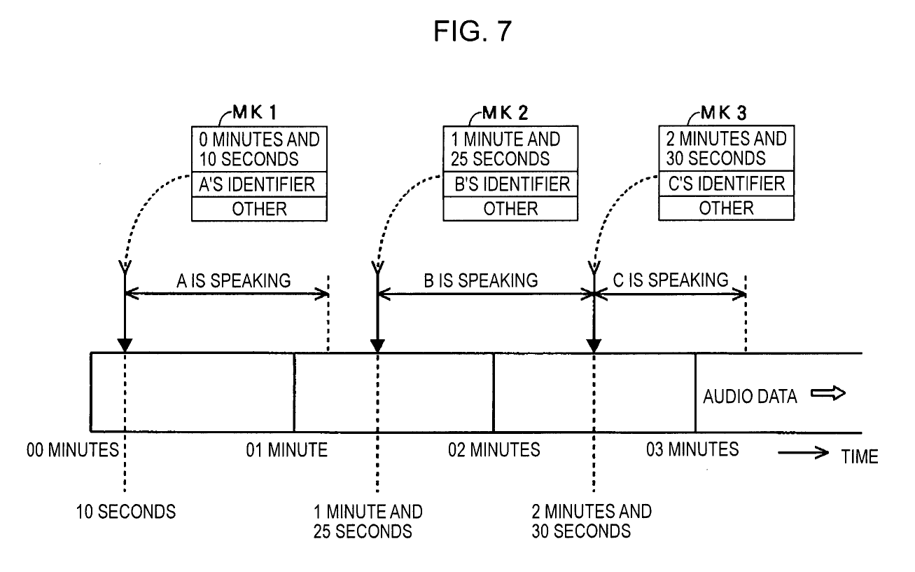

FIG. 7 is a diagram for explaining a scheme of a process for assigning marks to audio signals collected and recorded by the IC recorder according to the modification. The process for assigning marks is basically the same as that described with reference to FIG. 2. However, identifiers of speakers are attached to the marks.

As an example, a case where the proceedings of a meeting are recorded will be considered. Let it be supposed that A starts speaking 10 seconds after recording is started, as shown in FIG. 2. In this case, before A starts speaking, what is collected is silence, or meaningless sound that differs from clear speech, i.e., noise such as babble, the sound of pulling up a chair, or the sound of an item hitting a table. Thus, results of feature analysis of collected audio signals become clearly different from those before A starts speaking. The position of the point of change in the audio signals is identified (obtained), and the point-of-change information identified is stored as a mark MK1 in FIG. 7.

In this case, matching between the latest voiceprint data and voiceprint data in the audio-feature database is checked, and the identifier of a speaker (participant of the meeting) with matching voiceprint data is included in the mark MK1. FIG. 7 also shows an example where time elapsed since recording is started is stored as point-of-change information.

Let it be supposed further that B starts speaking a little after A stops speaking and that the period immediately before B starts speaking is a segment of silence or noise. Also in this case, when B starts speaking and B's speech is collected, results of feature analysis of the collected audio signals become clearly different from those before B starts speaking. Thus, as indicated by a mark MK2 in FIG. 7, point-of-change information (the mark MK2) is stored so that a mark is assigned to the start point of the B's speech.

Also in this case, matching between the latest voiceprint data and voiceprint data in the audio-feature database is checked, and the identifier of a speaker (participant of the meeting) with matching voiceprint data is included in the mark MK2.

Furthermore, it could occur that C interrupts while B is speaking. In that case, since the voice of B differs from the voice of C, results of analyzing collected audio signals differ between B and C. Thus, as indicated by a mark MK3 in FIG. 7, point-of-change information (the mark MK3) is stored in the data storage device 111 so that a mark is assigned to the start point of the C's speech.

Also in this case, matching between the latest voiceprint data and voiceprint data in the audio-feature database is checked, and the identifier of a speaker (participant of the meeting) with matching voiceprint data is included in the mark MK3.

In this manner, it is possible to identify which part of recorded audio signals is whose speech. For example, it is readily possible to play back only A's speech and to summarize A's speech.

As other information of the marks in this modification, for example, collected sound is converted into text data by speech recognition, and the text data is stored as other information in the form of a text data file. By using the text data file, it is possible to quickly prepare minutes or summary of speeches.

In the IC recorder according to the modification, it is possible to play back recorded sounds in a manner similar to the case described with reference to FIGS. 1, 3, and 5. Furthermore, in the case of the IC recorder according to the modification, it is possible to identify speech of each speaker in recorded sound without playing back the recorded sound.

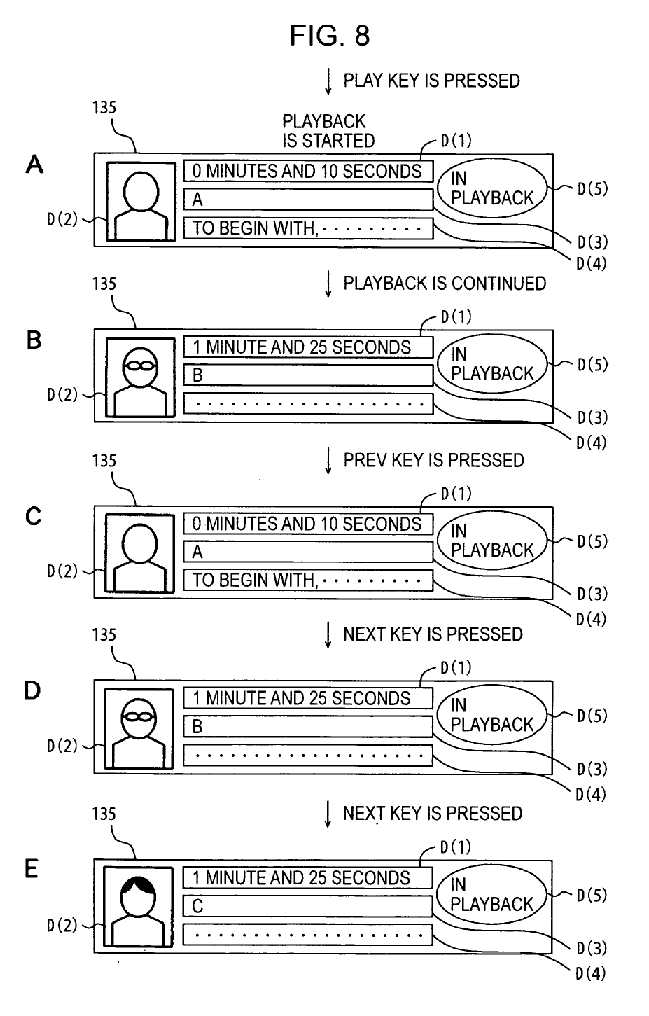

FIG. 8 is a diagram showing how information displayed on the LCD 135 changes in accordance with operations, which serves to explain an operation for setting playback position to the position of a mark when recorded audio signals are played back. As shown in FIG. 8, when the PLAY key 211 is pressed, as described earlier, the CPU 101 controls relevant components so that playback is started from the beginning of recorded audio signals specified.

In the part corresponding to A's speech, based on the mark MK1 assigned during the recording process as described with reference to FIG. 7, a start time D(1) of the speech, a picture D(2) of a face corresponding to image data of the speaker, a name D(3) of the speaker, and text data D(4) of the beginning part of the speech are displayed regarding A, and a playback mark D(5) is displayed, as shown in part A of FIG. 8.

Then, playback is continued, and when playback of the part corresponding to B's speech is started, based on the mark MK2 assigned during the recording process, a start time D(1) the speech, a picture D(2) of a face corresponding to image data of the speaker, a name D(3) of the speaker, and text data D(4) of the beginning part of the speech are displayed regarding B, and a playback mark D(5) is displayed, as shown in part B of FIG. 8.

Then, when the PREV key 215 is pressed, the CPU 101 sets the playback position to the start point of A's speech that is, at 10 seconds (0 minutes and 10 seconds) from the beginning, indicated by the mark MK1 so that playback is started therefrom, as shown in part C of FIG. 8. In this case, similarly to the case shown in part A of FIG. 8, a start time D(1) of the speech, a picture D(2) of a face corresponding to image data of the speaker, a name D(3) of the speaker, and text data D(4) of the beginning part of the speech are displayed regarding A, and a playback mark D(5) is displayed.

Then, when the NEXT key 214 is pressed, the CPU 101 sets the playback position to the start point of B's speech, that is, at 1 minute and 25 seconds after the beginning, indicated by the mark MK2, so that playback is started therefrom, as shown in part D of FIG. 8. In this case, similarly to the case shown in part B of FIG. 8, a start time D(1) of the speech, a picture D(2) of a face corresponding to image data of the speaker, a name D(3) of the speaker, and text data D(4) of the beginning part of the speech are displayed regarding B, and a playback mark D(5) is displayed.

When the NEXT key 214 is pressed again, the CPU 101 sets the playback position to the start point of C's speech, that is, at 2 minutes and 30 seconds from the beginning, indicated by the mark MK3, so that playback is started therefrom, as shown in part E of FIG. 8E. In this case, a start time D(1) of the speech, a picture D(2) of a face corresponding to image data of the speaker, a name D(3) of the speaker, and text data D(4) of the beginning part of the speech are displayed regarding C, and a playback mark D(5) is displayed.

In this modification, a mode may be provided in which when the NEXT key 214 or the PREV key 215 is quickly pressed twice, for example, while A's speech is being played back, the playback position is set to a next segment or a previous segment corresponding to A's speech so that playback is started therefrom. That is, by repeating this operation, it is possible to play back only parts corresponding to A's speech in a forward or backward order. Obviously, instead of the NEXT key 214 or the PREV key 215, an operation key dedicated for this mode may be provided. In that case, parts corresponding to A's speech are automatically played back in order.

As described above, in the IC recorder according to the modification, during the recording process, features of collected audio signals are automatically analyzed, and marks are assigned to points of change in features. During the playback process, by operating the NEXT key 214 or the PREV key 215, the playback position can be quickly set to a position of recorded audio signals as indicated by an assigned mark so that playback is started therefrom.

Furthermore, at the points of change in recorded audio signals, it is possible to clarify identification of the speaker by displaying a name or a picture of the face of the speaker. Thus, it is readily possible to quickly find speech of a speaker of interest, play back only parts corresponding to speech of a specific speaker, and so forth. Obviously, as information for identifying a speaker, an icon corresponding to icon data specific to each speaker may be displayed. Furthermore, it is possible to display text data of a beginning part of speech, which serves to distinguish whether the speech is of interest.

Furthermore, a user of the IC recorder according to the modification is allowed to quickly set the playback position to speech of a person of interest using information displayed during playback, and to play back and listen to recorded audio signals. Thus, the user can quickly prepare minutes regarding speech of interest.

That is, it is possible to visually recognize who spoke when without playing back recorded audio signals, so that it is readily possible to find speech of a specific speaker. Since information that facilitates identification of a speaker, such as a picture of the face of the speaker, can be used instead of a text string or a symbol, ease of searching is improved.

Furthermore, when a speaker is not identified, i.e., when the speaker is not registered yet or when the IC recorder fails to identify the speaker even though the speaker is already registered, a symbol indicating an unidentified speaker is assigned in association with speech of the unidentified speaker, so that the part can be readily found. In this case, a person who prepares minutes plays back the speech by the unregistered speaker and identifies the speaker.

When the unidentified speaker is identified as a registered speaker, a symbol associated with the speaker may be assigned as a mark. When the unidentified speaker is identified as an unregistered speaker, an operation for registering a new speaker may be performed. Features of the speaker's voice is extracted from recorded voice, and as the symbol associated therewith, a symbol registered in advance in the IC recorder or a text string input to the IC recorder, an image captured by a camera imaging function, if provided, of the IC recorder, image data obtained from an external device, or the like, is used.

A recording process in the IC recorder according to the modification is executed similarly to the recording process described with reference to FIG. 4. However, when marks MK1, MK2, MK3, . . . indicating speaker change are assigned in step S113, matching with voiceprint data in the audio-feature database is checked to assign identifiers of the relevant speakers. When corresponding voiceprint data is absent, a mark indicating the absence of corresponding voiceprint data is assigned.

A playback process in the IC recorder according to the modification is executed similarly to the playback process described with reference to FIG. 5. However, when information indicating the playback position is displayed in step S217, a picture of the face of the speaker, a name of the speaker, text data representing the content of speech, and the like, are displayed.

Although time elapsed from a start point of recording is used as point-of-change information in the IC recorder according to the modification, without limitation thereto, an address of recorded audio signals on a recording medium of the data storage device ill may be used as point-of-change information.

### Timing of Executing Process for Assigning Marks

In the IC recorder according to the first embodiment and the IC recorder according to the modification of the first embodiment, points of change in collected sound are detected and marks are assigned to positions of audio signals corresponding to the points of charge in a recording process. However, without limitation to the first embodiment and the modification, marks may be assigned after a recording process is finished. That is, marks may be assigned during a playback process, or a mark assigning process may be executed independently.

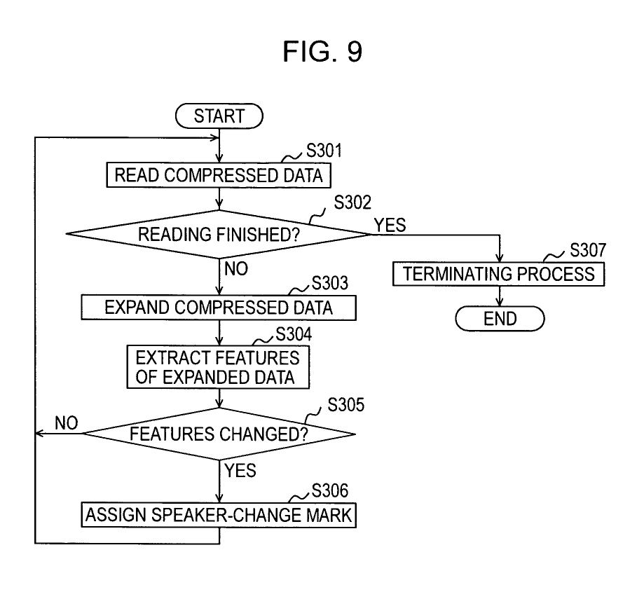

FIG. 9 is a flowchart of a process for assigning marks to points of change in recorded audio signals after a recording process is finished. That is, the process shown in FIG. 9 is executed when marks are assigned to points of change in recorded sound during a playback process or when a process for assigning marks to points of change in recorded sound is executed independently. The process shown in FIG. 9 is also executed by the CPU 101 of the IC recorder controlling relevant components.

The CPU 101 instructs the file processor 110 to read compressed recorded audio signals stored in the audio file of the data storage device 111, by units of a predetermined size (step S301), and determines whether all the recorded audio signals have been read (step S302).

If it is determined in step S302 that all the recorded audio signals have not been read, the CPU 101 instructs the data expander 142 to expand the compressed recorded audio signals (step S303). Then, the CPU 101 instructs the audio-feature analyzer 143 to analyze features of the expanded audio signals to obtain voiceprint data, and compares the voiceprint data with voiceprint data obtained earlier, thereby determining whether features of recorded audio signals have changed (step S305).

If it is determined in step S305 that features of the recorded audio signals have not changed, the process is repeated from step S301. If it is determined in step S305 that features of the recorded audio signals have changed, the CPU 101 determines that the speaker has changed, and instructs the file processor 110 to assign a mark to the point where audio features have changed (step S306).

Thus, the file processor 110 writes information indicating time elapsed from the beginning of the file or information indicating an address corresponding to a recording position to the database area 111(1) of the data storage device 111, as information indicating a point of change in audio features regarding the audio file 111(2). In this case, the audio file and the information indicating the point of change in audio features are stored in association with each other.

After step S306, the CPU 101 repeats the process from step S301 on audio signals of the next period (next processing unit). Then, if it is determined in step S302 that all the recorded audio signals have been read, a predetermined terminating process is executed (step S307), and the process shown in FIG. 9 is exited.

Thus, after the recording process, it is possible to detect points of change in the recorded sound during the playback process and assign marks to the recorded sound, or to independently execute the process of assigning marks to the recorded sound. When marks are assigned in the playback process, audio signals expanded in step S303 shown in FIG. 9 are D/A-converted and the resulting analog audio signals are supplied to the speaker 133.

As described above, by assigning marks to points of change in features of recorded audio signals after recording, processing load and power consumption for recording can be reduced. Furthermore, since it is possible that a user does not wish to automatically assign marks in every recording, setting as to whether or not to automatically assign marks during recording may be allowed. When the user executes recording with the automatic mark assigning function turned off and later wishes to assign marks, the user is allowed to assign marks to recorded audio signals even after the recording process as described above, which is very convenient.

Furthermore, since marks can be assigned to recorded audio signals as described above, application to apparatuses not having a recording function but having a signal processing function is possible. For example, the embodiment may be applied to application software for personal computers. In that case, audio signals recorded by an audio recording apparatus is transferred to a personal computer so that marks can be assigned by the signal processing application software running on the personal computer.

Furthermore, by sharing data created by an apparatus according to this embodiment via a network or the like, it is possible to use the data itself as minutes without transcribing the data.

Thus, the embodiment is applicable to various electronic apparatuses capable of signal processing, without limitation to recording apparatuses. Thus, similar results can be obtained with audio signals already recorded, by processing the audio signals using an electronic device according to the embodiment. That is, minutes can be prepared efficiently.

Furthermore, as described earlier, the IC recorder according to the first embodiment shown in FIG. 1 includes the communication I/F 144, so that the IC recorder can be connected to an electronic apparatus, such as a personal computer. Thus, by transferring digital audio signals recorded by the IC recorder, including marks assigned to points of change, to the personal computer, it is possible to display more detailed information on a display of the personal computer, having a large screen. This allows quick searching for speech of a speaker of interest.

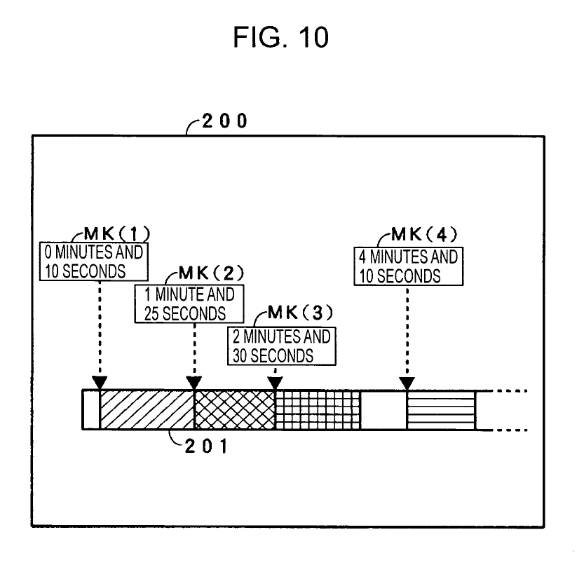

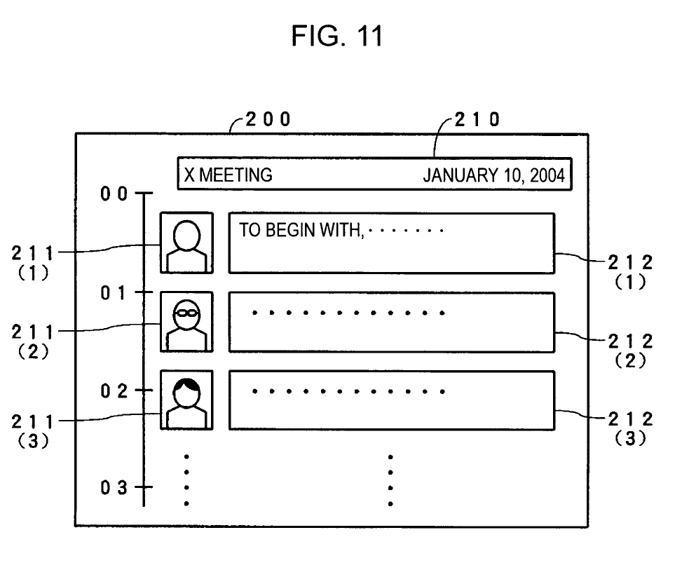

FIGS. 10 and 11 are diagrams showing examples of displaying point-of-change information on a display screen of a display 200 connected to a personal computer, based on recorded audio signals and point-of-change information (mark information) assigned thereto, transferred from the IC recorder according to the first embodiment to the personal computer.

In the example shown in FIG. 10, a time-range indication 201 associated with recorded audio signals is displayed, and marks (points of change) MK1, MK2, MK3, MK4 . . . are displayed at appropriate positions of the time-range indication 201. Thus, it is possible to recognize positions of a plurality of points of change at a glance. Furthermore, for example, by clicking a mark with a cursor placed thereon, using a pointing device such as a mouse, it is possible to play back recorded sound therefrom.

In the example shown in FIG. 11, a plurality of sets of the items shown in FIG. 8 is simultaneously displayed on the display screen of the display 200. More specifically, pictures 211(1), 211(2), 211(3) . . . of the faces of speakers, and text data 212(1), 212(2), 212(3) . . . corresponding to the contents of speeches are displayed, allowing quick searching of speech of a speaker of interest. Furthermore, it is possible to display a title indication 210 using a function of the personal computer.

In the example shown in FIG. 11, “00”, “01”, “02”, “03” . . . on the left side indicate time elapsed from the beginning of recorded sound. Obviously, various modes of display may be implemented, for example, a mode in which a plurality of sets of items shown in FIG. 8 is displayed.

By transferring data in which recorded speeches are identified with information (symbols) identifying speakers to an apparatus having a large display, such as a personal computer, it is possible to prepare minutes without transcribing audio data. That is, data recorded by the IC recorder according to this embodiment directly serves as minutes.

Furthermore, with software such as a plug-in that allows data to be made available on a Web page and browsed by a Web browser, it is possible to share minutes via a network. This serves to considerably reduce labor and time for sharing information, i.e., for making information available.

### Second Embodiment

### Overview of Construction and Operation of IC Recorder

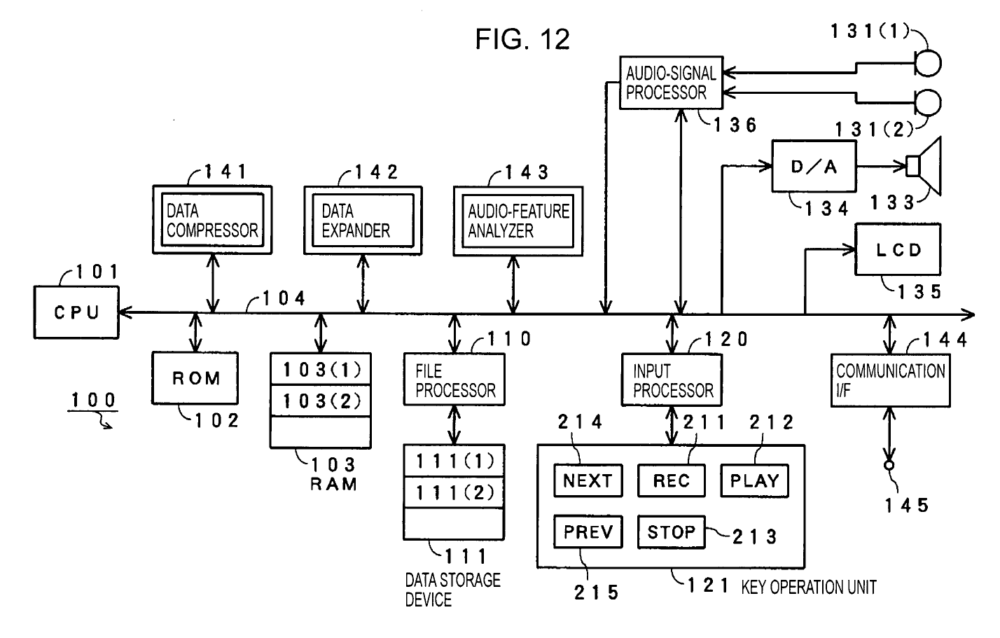

FIG. 12 is a block diagram of an IC recorder that is a recording/playback apparatus according to a second embodiment of the present invention. The IC recorder according to the second embodiment is constructed the same as the IC recorder according to the first embodiment shown in FIG. 1, except in that two microphones 131(1) and 131(2) and an audio-signal processor 136 for processing audio signals input from the two microphones 131(1) and 131(2) are provided. Thus, with regard to the IC recorder according to the second embodiment, parts corresponding to those of the IC recorder according to the first embodiment are designated by the same numerals, and detailed descriptions thereof will be omitted.

In the IC recorder according to the second embodiment, collected audio signals input from the two microphones 131(1) and 131(2) are processed by the audio-signal processor 136 to identify a speaker position (sound-source position), so that a point of change in the collected audio signals (point of speaker change) can be identified with consideration of the speaker position. That is, when a point of change in collected audio signals is detected using voiceprint data obtained by audio analysis, a speaker position based on sound collected by the two microphones is used as auxiliary information so that a point of change or a speaker can be identified more accurately.

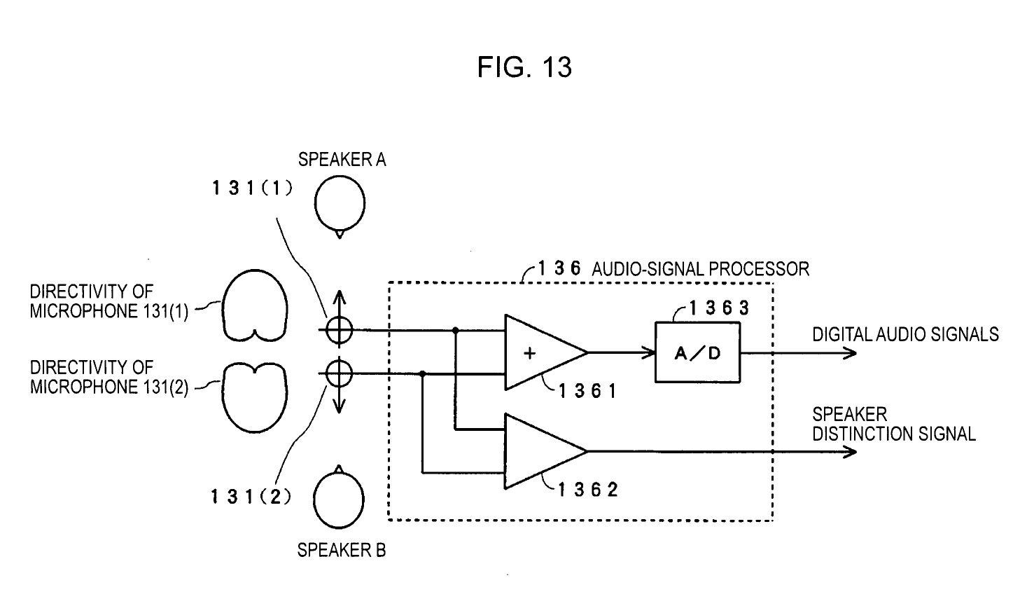

FIG. 13 is a diagram showing an example construction of the microphones 131(1) and 131(2) and the audio-signal processor 136. In the example shown in FIG. 13, each of the two microphones 131(1) and 131(2) is unidirectional, as shown in FIG. 13. The microphones 131(1) and 131(2) are disposed back to back in proximity to each other so that the main directions of the directivities thereof are opposite. Thus, the microphone 131(1) favorably collects speech of a speaker A, while the microphone 131(2) favorably collects speech of a speaker B.

As shown in FIG. 13, the audio-signal processor 136 includes an adder 1361, a comparator 1362, and an A/D converter 1363. Audio signals collected by each of the microphones 131(1) and 131(2) are supplied to the adder 1361 and to the comparator 1362.

The adder 1361 adds together the audio signals collected by the microphone 131(1) and the audio signals collected by the microphone 131(2), and supplies the sum of audio signals to the A/D converter 1363. The sum of the audio signals collected by the microphone 131(1) and the audio signals collected by the microphone 131(2) can be expressed by equation (1) below, and is equivalent to audio signals collected by a non-directional microphone.
((1+cos θ)/2)+((1−cos θ)/2)=1 (1)

The comparator 1362 compares the audio signals collected by the microphone 131(1) and the audio signals collected by the microphone 131(2). When the level of the audio signals collected by the microphone 131(1) is higher, the comparator 1362 determines that the speaker A is mainly speaking, and supplies a speaker distinction signal having a value of “1” (High level) to the controller 100. On the other hand, when the level of the audio signals collected by the microphone 131(2) is higher, the comparator 1362 determines that the speaker B is mainly speaking, and supplies a speaker distinction signal having a value of “0” (Low level) to the controller 100.

Thus, a speaker position is identified based on the audio signals collected by the microphone 131(1) and the audio signals collected by the microphone 131(2), allowing distinction between speech of the speaker A and speech of the speaker B.

If a third speaker C speaks from a direction traversing the main directions of directivities of the microphones 131(1) and 131(2), i.e., from a position diagonally facing the speakers A and B (a lateral direction in FIG. 13), the levels of audio signals collected by the microphones 131(1) and 131(2) are substantially equal to each other.

In order to deal with speech by the speaker C at such a position, two thresholds may be defined for the comparator 1362, determining that the speaker is the speaker C in the lateral direction when the difference in level is within ±Vth, the speaker is the speaker A when the difference in level is greater than +Vth, and the speaker is the speaker B when the difference in level is less than −Vth.

By recognizing in advance the speaker in the direction of the directivity of the microphone 131(1), the speaker in the direction of the directivity of the microphone 131(2), and the speaker in the direction traversing the directions of directivities of the microphones 131(1) and 131(2), identification of the speaker is allowed. Thus, when a point of change is detected based on voiceprint data obtained by analyzing features of collected sound, the speaker can be identified more accurately by considering the levels of sound collected by the microphones.

### Another Example of Microphones and Audio-Signal Processor

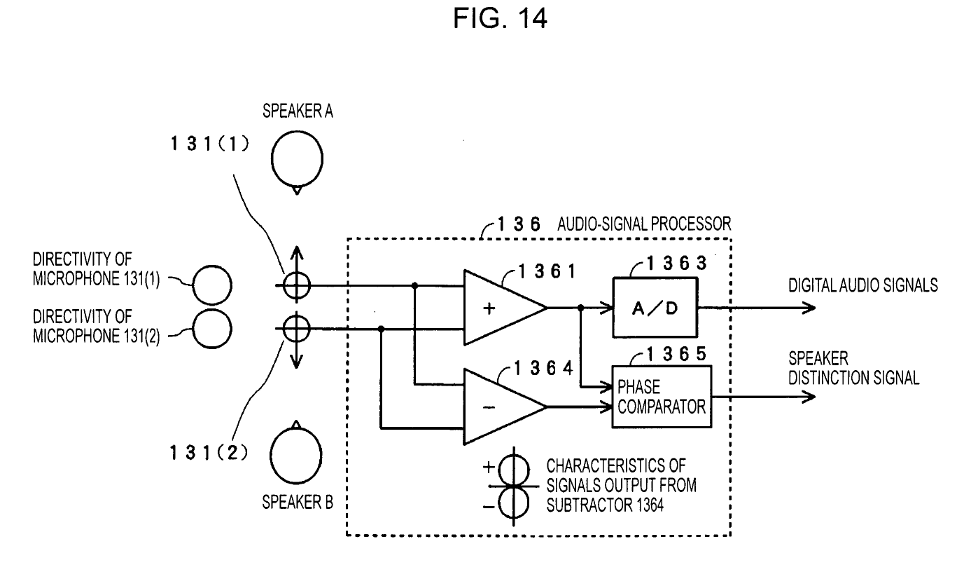

Alternatively, the microphones 131(1) and 131(2) and the audio-signal processor 136 may be constructed as shown in FIG. 14. FIG. 14 is a diagram showing another example construction of the microphones 131(1) and 131(2) and the audio-signal processor 136. In the example shown in FIG. 14, the two microphones 131(1) and 131(2) are non-directional, as shown in FIG. 14. The microphones 131(1) and 131(2) are disposed in proximity to each other, for example, with a gap of approximately 1 cm therebetween.

As shown in FIG. 14, the audio-signal processor 136 in this example includes an adder 1361, an A/D converter 1363, a subtractor 1364, and a phase comparator 1365. Audio signals collected by each of the microphones 131(1) and 131(2) are supplied to the adder 1361 and to the subtractor 1364.

A sum signal output from the adder 1361 is equivalent to an output of a non-directional microphone, and a subtraction signal output from the subtractor 1364 is equivalent to an output of a bidirectional (8-figure directivity) microphone. The phase of an output of a bidirectional microphone is positive or negative depending on the incident direction of acoustic waves. Thus, the phase of a sum output (non-directional output) of the adder 1361 and the phase of the subtraction output of the subtractor 1364 are compared with each other by the phase comparator 1365 to determine the polarity of the subtraction output of the subtractor 1364, thereby identifying the speaker.

That is, when the polarity of the subtraction output of the subtractor 1364 is positive, it is determined that speech by the speaker A is being collected. On the other hand, when the polarity of the subtraction output of the subtractor 1364 is negative, it is determined that speech by the speaker B is being collected.

Furthermore, similarly to the case described with reference to FIG. 13, when speech by the speaker C diagonally facing the speakers A and B (in the lateral direction in FIG. 14) is to be dealt with, the level of the subtraction output of collected audio signals corresponding to the speech by the speaker C is small. Thus, by checking the levels of the sum output of the adder 1361 and the subtraction output of the subtractor 1364, it is possible to recognize speech by the speaker C.

Although the audio-signal processor 136 shown in FIG. 14 includes the adder 1361, the adder 1361 is not a necessary component. For example, one of the output signals of the microphones 131(1) and 131(2) may be supplied to the A/D converter 1363 and to the phase comparator 1365.

As described above, in the examples shown in FIGS. 13 and 14, in the recording process, it is possible to identify a speaker position using the levels or polarities of sound collected by the two microphones 131(1) and 131(2). Furthermore, by considering the result of identification, it is possible to detect a point of change in the collected sound and to identify a speaker accurately.

The schemes shown in FIGS. 13 and 14 can be employed when marks are assigned to recorded sound during the playback process or when a process for assigning marks to recorded sound is executed independently.

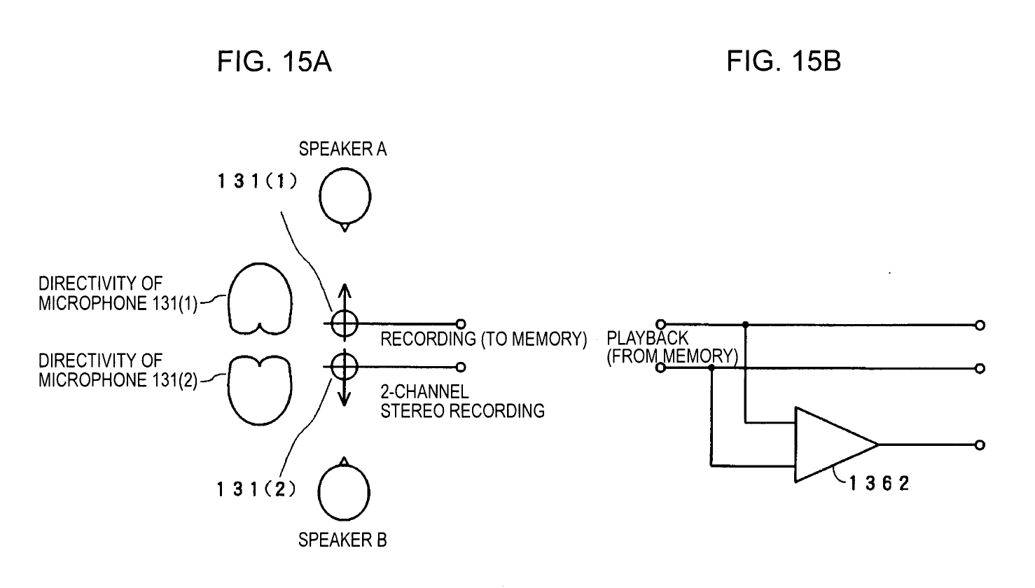

For example, when the scheme described with reference to FIG. 13 is used after the recording process, audio signals collected by the unidirectional microphones 131(1) and 131(2) are recorded by 2-channel stereo recording, as shown in FIG. 15A. During the playback process or when a process for assigning marks is executed independently, compressed audio signals of the two channels, read from the data storage device 111, are expanded, and the expanded audio signals of the two channels are input to a comparator having the same function as the comparator 1362 shown in FIG. 13.

Thus, it is possible to determine whether audio signals collected by the microphone 131(1) have been mainly used or audio signals collected by the microphone 131(2) have been mainly used. Thus, it is possible to identify a speaker based on the result of determination and the positions of speakers relative to each of the microphones known in advance.

Similarly, when the scheme described with reference to FIG. 14 is used after the recording process, signals output from the microphones 131(1) and 131(2) are recorded by two-channel stereo recording, and during the playback process or when a process for assigning marks is executed independently, a speaker can be identified by the same process executed by audio-signal processor 136 shown in FIG. 14.

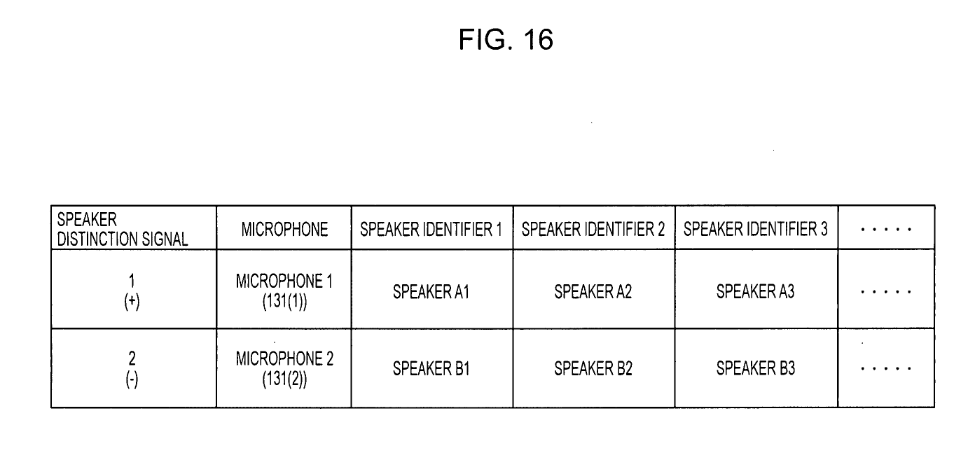

When a speaker is identified using signals output from the microphones 131(1) and 131(2), information indicating positions of speakers relative to each of the microphones 131(1) and 131(2), prepared in advance, is stored in the IC recorder, for example, in the form of a speaker-position database shown in FIG. 16.

FIG. 16 is a diagram showing an example of speaker-position database. In this example, the speaker-position database includes speaker distinction signals corresponding to results of identification from the audio-signal processor 136 of the IC recorder, identification information of microphones associated with the respective speaker distinction signals, and speaker identifiers of candidates of speakers who mainly use the microphones. As shown in FIG. 16, it is possible to register a plurality of microphones in association with a single microphone.

The speaker-position database shown in FIG. 16 is preferably created in advance of a meeting. Generally, participants of a meeting and seats of the participants are determined in advance. Thus, it is possible to create a speaker-position database in advance of a meeting, with consideration of where the IC recorder is set.

When participants of a meeting are changed without an advance notice, or when seats are changed during a meeting, for example, recognition of a speaker based on sound collected by microphones is not used, and points of change are detected based only on voiceprint data obtained by audio analysis. Alternatively, the speaker-position database may be adjusted to be accurate after the recording process, reassigning marks to recorded sound.

By using the speaker-position database shown in FIG. 16, it is possible to identify a speaker position and to identify a speaker at the speaker position.

Although the two microphones 131(1) and 131(2) are used and two or three speakers are involved in the second embodiment, the number of microphones is not limited to two, and the number of speakers is not limited to three. Use of a larger number of microphones allows identification of a larger number of speakers.

Furthermore, schemes for identifying a speaker by identifying a position of the speaker based on signals output from microphones are not limited to those described with reference to FIGS. 13 and 14. For example, closely located four point microphone method or closely located three point microphone method may be used.

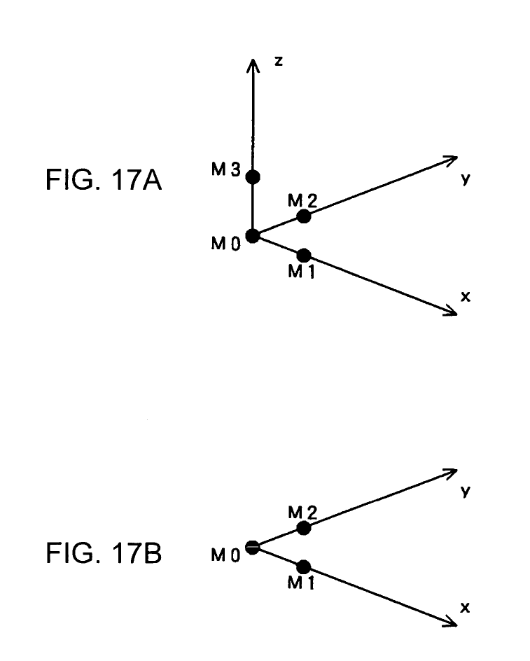

In the closely located four point microphone method, four microphones M0, M1, M2, and M3 are located in proximity to each other so that one of the microphones is not in a plane defined by the other three microphones, as shown in FIG. 17A. Considering slight difference in temporal structures of audio signals collected by the four microphones M0, M1, M2, and M3, spatial information such as position or size of an acoustic source is calculated by short-time correlation, acoustic intensity, or the like. In this way, by using at least four microphones, it is possible to identify a speaker position accurately and to identify a speaker based on the speaker position (seat position).

When it is acceptable to assume that speakers are substantially in a horizontal plane, it suffices to provide three microphones provided in a horizontal plane in proximity to each other, as shown in FIG. 17B.

Furthermore, the arrangement of microphones need not be orthogonal as shown in FIGS. 17A and 17B. In the case of the closely located three point microphone method shown in FIG. 17B, for example, the arrangement of microphones may be such that three microphones are disposed at the vertices of an equilateral triangle.

### Modification of Second Embodiment

In the IC recorder according to the second embodiment described above, when points of change in collected audio signals are detected using voiceprint data obtained by audio analysis, a result of distinction of microphones mainly used is considered based on sound collected from two microphones so that the precision of detection of points of change in audio signals is improved. However, other arrangements are possible.

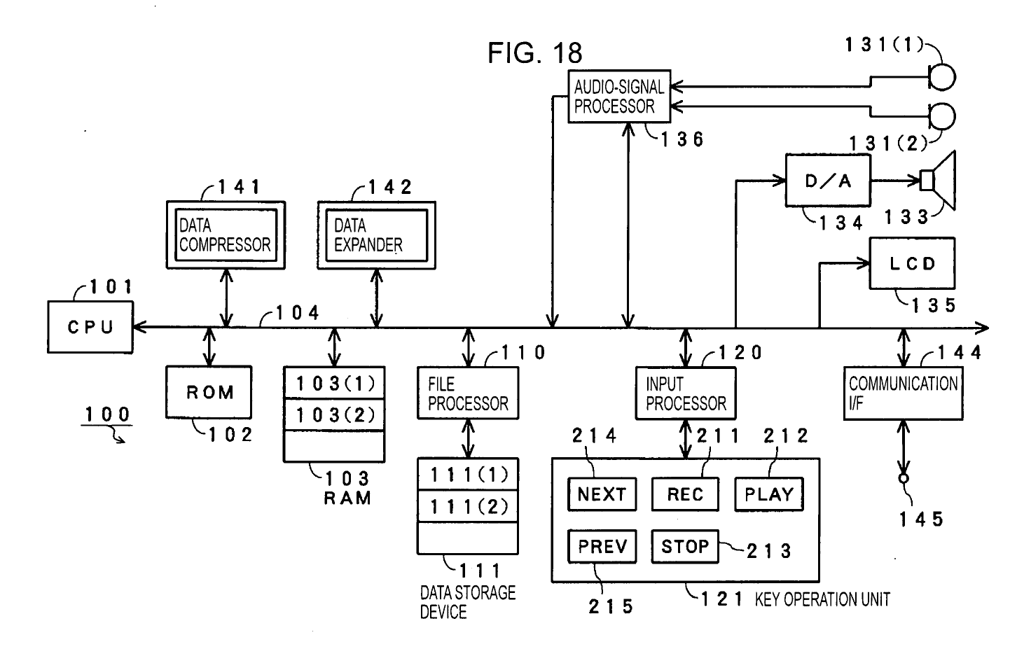

For example, an IC recorder including the two microphones 131(1) and 131(2) and an audio-signal processor 136 but not including the audio-feature analyzer 143 may be provided, as shown in FIG. 18. That is, the IC recorder shown in FIG. 18 is constructed the same as the IC recorder according to the second embodiment shown in FIG. 12 except in that the audio-feature analyzer 143 is not provided.

It is possible to detect points of speaker change based on only a result of distinction of microphones that are mainly used, based on sound collected by the two microphones 131(1) and 131(2), speaker change is detected based on a result of discrimination of a microphone that is mainly used, assigning marks to positions of audio signals corresponding to the points of change. In this case, processing for analyzing audio features is not needed, so that the load of the CPU 101 is reduced.

Although marks are assigned to points of change in audio signals to be processed in the embodiments described above, it is possible to assign marks only to points of speaker change so that more efficient searching is possible. For example, based on signal levels or voiceprint data of audio signals to be processed, speech segments are clearly distinguished from other segments such as noise, assigning marks only to the start points of speech segments.

Furthermore, based on voiceprint data or feature data of frequencies of audio signals, it is possible to distinguish whether a speaker is a male or a female, reporting the distinction of sex of the speaker at points of change.

Furthermore, based on mark information assigned in the manner described above, for example, a searching mode for searching only, a mark editing mode for changing positions of marks assigned, deleting marks, or adding marks, or a special playback mode for playing back only speech of a speaker that can be specified based on marks assigned, for example, only A's speech, may be provided. These modes can be implemented relatively easily by adding codes to programs executed by the CPU 101.

Furthermore, a database updating function may be provided so that for example, voiceprint data in the audio-feature database shown in FIG. 6 can be updated with voiceprint data used for detecting points of change, thereby improving accuracy the audio-feature database. For example, even when voiceprint data of a speaker does not find a match in the process of comparing voiceprint data, if voiceprint data of the speaker actually exist in the audio-feature database, the voiceprint data in the audio-feature database is replaced with the voiceprint data newly obtained.

Furthermore, when voiceprint data of a speaker matches voiceprint data of a different speaker in the comparing process, setting can be made so that the voiceprint data of the different speaker is not used in the comparing process.

When voiceprint data matches voiceprint data of a plurality of speakers, priority is defined for voiceprint data used so that the voiceprint data matches only voiceprint data of a correct speaker.

Furthermore, marks may be assigned to end points as well as start points of speeches. Furthermore, positions where marks are assigned may be changed, for example, to some seconds after or before start points, in consideration of the convenience of individual users.

Furthermore, as described earlier, one or more of various methods may be used for analyzing features of audio signals, without limitation to voiceprint analysis, so that precise analysis data can be obtained.

Although the second embodiment has been described above mainly in the context of an example where two microphones are used, the number of microphones is not limited to, and may be any number not smaller than two. A speaker position is identified using various parameters such as signal levels, polarities, or delay time for collection of sound collected by the individual microphones, allowing identification of the speaker based on the speaker position.

Furthermore, although the first and second embodiments have been described in the context of examples where the present invention is applied to an IC recorder, which is an apparatus for recording and playing back audio signals, the application of the present invention is not limited to IC recorders. For example, the present invention can be applied to recording apparatuses, playback apparatuses, and recording/playback apparatuses used with various recorded media, for example, magneto-optical disks such as hard disks and MDs or optical disks such as DVDs.

### Software Implementation

The present invention can also be implemented using a program that, when executed by the CPU 101, achieves the functions of the audio-feature analyzer 143, the audio-signal processor 136, and other processing units of the IC recorder according to the embodiments described above and that effectively links the functions. That is, the present invention can be implemented by preparing a program for executing the processes shown in the flowcharts in FIGS. 4 and 5 and executing the program by the CPU 101.

Furthermore, similarly to the embodiments described above, audio data recorded by a recorder can be captured by a personal computer having installed thereon a program implementing the function of the audio-feature analyzer 143 so that the personal computer can detect speaker change.

1. An audio-signal processing apparatus comprising:
first detecting means for detecting speaker change in audio signals to be processed, based on the audio signals, on a basis of individual processing units having a predetermined size;
obtaining means for obtaining point-of-change information indicating a position of the audio signals where the first detecting means has detected a speaker change; and
holding means for holding the point-of-change information obtained by the obtaining means.

2. The audio-signal processing apparatus according to claim 1, wherein the first detecting means is capable of extracting features of the audio signals on the basis of the individual processing units, and detecting a point of change from a non-speech segment to a speech segment and a point of speaker change in a speech segment based on the features extracted.

3. The audio-signal processing apparatus according to claim 2, further comprising:
storage means for storing one or more pieces of feature information representing features of speeches of one or more speakers, and one or more pieces of identification information of the one or more speakers, the pieces of feature information and the pieces of identification information being respectively associated with each other; and
identifying means for identifying a speaker by comparing the features extracted by the first detecting means with the pieces of feature information stored in the storage means;
wherein the holding means holds the point-of-change information and a piece of identification information of the speaker identified by the identifying means, the point-of-change information and the piece of identification information being associated with each other.

4. The audio-signal processing apparatus according to claim 2, further comprising second detecting means for detecting a speaker position by analyzing audio signals of a plurality of audio channels respectively associated with a plurality of microphones, wherein the obtaining means identifies a point of change in consideration of change in speaker position detected by the second detecting means, and obtains point-of-change information corresponding to the point of change identified.

5. The audio-signal processing apparatus according to claim 3, further comprising:
speaker-information storage means for storing speaker positions determined based on audio signals of a plurality of audio channels respectively associated with a plurality of microphones, and pieces of identification information of speakers at the respective speaker positions, the speaker positions being respectively associated with the pieces of identification information; and
speaker-information obtaining means for obtaining, from the speaker-information storage means, a piece of identification information of a speaker associated with a speaker position determined by analyzing the audio signals of the plurality of audio channels;
wherein the identifying means identifies the speaker in consideration of the identification information obtained by the speaker-information obtaining means.

6. The audio-signal processing apparatus according to claim 3, further comprising display-information processing means, wherein the storage means stores pieces of information respectively relating to the speakers corresponding to the respective pieces of identification information, the pieces of information being respectively associated with the respective pieces of identification information, and the display-information processing means displays a position of a point of change in the audio signals and a piece of information relating to the speaker identified by the identifying means.

7. The audio-signal processing apparatus according to claim 1, wherein the first detecting means detects speaker change based on a speaker position determined by analyzing audio signals of respective audio channels, the audio signals being collected by different microphones.

8. The audio-signal processing apparatus according to claim 7, wherein the holding means holds the point-of-change information and information indicating the speaker position detected by the first detecting means, the point-of-change information and the information indicating the speaker position being associated with each other.

9. The audio-signal processing apparatus according to claim 7, further comprising:
speaker-information storage means for storing speaker positions determined based on audio signals of a plurality of audio channels respectively associated with a plurality of microphones, and pieces of identification information of speakers at the respective speaker positions, the speaker positions being respectively associated with the pieces of identification information; and
speaker-information obtaining means for obtaining, from the speaker-information storage means, a piece of identification information of a speaker associated with a speaker position determined by analyzing the audio signals of the plurality of audio channels;
wherein the holding means holds the point-of-change information and the piece of identification information obtained by the speaker-information obtaining means, the point-of-change information and the piece of identification information being associated with each other.

10. The audio-signal processing apparatus according to claim 9, further comprising display-information processing means, wherein the speaker-information storage means stores pieces of information respectively relating to the speakers corresponding to the respective pieces of identification information, the pieces of information being respectively associated with the respective pieces of identification information, and the display-information processing means displays a position of a point of change in the audio signals and a piece of information relating to the speaker associated with the speaker position determined.

11. An audio-signal processing method comprising:
a first detecting step of detecting speaker change in audio signals to be processed, based on the audio signals, on a basis of individual processing units having a predetermined size;
an obtaining step of obtaining point-of-change information indicating a position of the audio signals where a speaker change has been detected in the first detecting step; and
a storing step of storing the point-of-change information obtained in the obtaining step on a recording medium.

12. The audio-signal processing method according to claim 11, wherein features of the audio signals are extracted on the basis of the individual processing units in the first detecting step, and a point of change from a non-speech segment to a speech segment and a point of speaker change in a speech segment are detected based on the features extracted.

13. The audio-signal processing method according to claim 12, further comprising an identifying step of identifying a speaker by comparing the features extracted in the first detecting step with one or more pieces of feature information representing features of speeches of one or more speakers, the pieces of feature information being stored on a recording medium respectively in association with one or more pieces of identification information of the one or more speakers, wherein the point-of-change information and a piece of identification information of the speaker identified in the identifying step are stored on the recording medium in association with each other in the storing step.

14. The audio-signal processing method according to claim 12, further comprising a second detecting step of detecting a speaker position by analyzing audio signals of a plurality of audio channels respectively associated with a plurality of microphones, wherein in the obtaining step, a point of change is identified in consideration of change in speaker position detected in the second detecting step, and point-of-change information corresponding to the point of change identified is obtained.

15. The audio-signal processing method according to claim 13, further comprising:
a speaker-information storing step of storing, on speaker-information storage means in advance, speaker positions determined based on audio signals of a plurality of audio channels respectively associated with a plurality of microphones, and pieces of identification information of speakers at the respective speaker positions, the speaker positions being respectively associated with the pieces of identification information; and
a speaker-information obtaining step of obtaining, from the speaker-information storage means, a piece of identification information of a speaker associated with a speaker position determined by analyzing the audio signals of the plurality of audio channels;
wherein the speaker is identified in the identifying step in consideration of the identification information obtained in the speaker-information obtaining step.

16. The audio-signal processing method according to claim 13, further comprising a display-information processing step, wherein pieces of information respectively relating to the speakers corresponding to the respective pieces of identification information are stored on the recording medium respectively in association with the respective pieces of identification information, and a position of a point of change in the audio signals and a piece of information relating to the speaker identified in the identifying step are displayed in the display-information processing step.

17. The audio-signal processing method according to claim 11, wherein a point of change is detected in the first detecting step based on a speaker position determined by analyzing audio signals of respective audio channels, the audio signals being collected by different microphones.

18. The audio-signal processing method according to claim 17, wherein the point-of-change information and information indicating the speaker position detected in the first detecting step are stored in association with each other in the storing step.

19. The audio-signal processing method according to claim 17, further comprising:
a speaker-information storing step of storing, on speaker-information storage means in advance, speaker positions determined based on audio signals of a plurality of audio channels respectively associated with a plurality of microphones, and pieces of identification information of speakers at the respective speaker positions, the speaker positions being respectively associated with the pieces of identification information; and
a speaker-information obtaining step of obtaining, from the speaker-information storage means, a piece of identification information of a speaker associated with a speaker position determined by analyzing the audio signals of the plurality of audio channels;
wherein the point-of-change information and the piece of identification information obtained in the speaker-information obtaining step are stored in association with each other in the storing step.

20. The audio-signal processing method according to claim 19, further comprising a display-information processing step, wherein the storage means stores pieces of information respectively relating to the speakers corresponding to the respective pieces of identification information, the pieces of information being respectively associated with the respective pieces of identification information, and a position of a point of change in the audio signals and a piece of information relating to the speaker associated with the speaker position determined are displayed in the display-information processing step.
